(19) United States
(12) Patent Application Publication
(10) Pub. No.: US 2010/0118626 A1
(43) Pub. Date: May 13, 2010

(54) Delay device for shifting phase of strobe signal

(75) Inventor: Kouji Maeda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/588,492

(22) Filed: Oct. 16, 2009

(30) Foreign Application Priority Data
Nov. 10, 2008 (JP) 2008-287405

(51) Int. Cl. G11C 7/00; G11C 8/00; H03L 7/06

(52) U.S. Cl. 365/193; 365/194; 365/233.1; 327/158; 365/189.05

(57) ABSTRACT

A delay apparatus includes a DLL circuit including a delay element, the DLL circuit generating a first control signal for controlling the delay element in order that the delay element delays a reference clock inputted into the delay element by one cycle, and a strobe delay element having a configuration identical to a configuration of the delay element, the strobe delay element delaying the strobe signal inputted from an outside by an amount of delay corresponding to a second control signal. The delay apparatus further includes a strobe delay controlling circuit obtaining the second control signal, from the first control signal and an expectation value for the amount of delay to be made by the strobe delay element, and a clock supplying circuit supplying the DLL circuit with the reference clock having a frequency higher than a frequency of the strobe signal.

### INCORPORATION BY REFERENCE

This application is based upon and claims the benefit of priority from Japanese Patent Application No. 2008-287405 which was filed on Nov. 10, 2008, the disclosure of which is incorporated herein in its entirety by reference.

### BACKGROUND OF THE INVENTION

1. Field of the Invention

The present invention relates to a delay control, and particularly to a delay controlling technique for a circuit that latches data by shifting the phase of a strobe signal from outside.

2. Description of Related Art

There has been a method for latching data by delaying a strobe signal like a DDR (Double Data Rate) interface for a DRAM (Dynamic Random Access Memory), which is disclosed, for example, in Japanese Patent Application Laid Open No. 2007-336028).

In the method, a data sender device simultaneously sends a data signal and a strobe signal which is synchronized with the data signal, or which is shifted by a certain phase difference. By use of the strobe signal, a data receiver device identifies the timing for receiving the data and latches the data.

For implementing these operations on an LSI, the phase of the strobe signal from outside needs to be controlled. Here, since the strobe signal from outside is an intermittent clock, a delay apparatus including a DLL (Delay Locked Loop) circuit is used.

FIG. 5 shows a delay apparatus 10 of a related art. The delay apparatus 10 includes a DLL circuit 20, a delay setting value calculating circuit 30, and a delay element 40. The DLL circuit 20 includes a delay element 22, a phase comparing circuit 24, and a control circuit 26.

In the DLL circuit 20, the delay element 22 is a variable delay element set to have a delay value obtained by multiplying a predetermined unit delay by a certain integer. The delay element 22 delays a reference clock, and outputs the delayed reference clock to the phase comparing circuit 24. The phase comparing circuit 24 compares the phase of the reference clock before being inputted into the delay element 22 with the phase of the reference clock having been delayed by the delay element 22, and thus outputs a differential signal to the control circuit 26. The control circuit 26 sets a delay setting value (a first control signal) corresponding to the differential signal from the phase comparing circuit 24, and executes feedback control of the delay applied by the delay element 22. With this configuration, the DLL circuit 20 finally turns into a stable state with an amount of delay which causes the reference clock to be delayed by one cycle.

The delay setting value (the first control signal) which the control circuit 26 sets for the delay element 22 is also outputted to the delay setting value calculating circuit 30. The delay setting value calculating circuit 30 calculates a delay setting value (a second control signal) for the delay element 40 which delays the strobe signal on the basis of the first control signal from the control circuit 26 and a phase setting value. Note that the “phase setting value” is an expectation value for the amount of delay by which the delay element 40 delays the strobe signal. The delay element 40 has the same configuration, including a layout, and the same number of stages, as the delay element 22 has. In addition, the strobe signal and the reference clock have the same frequency.

The strobe signal from outside is inputted into the delay element 40 which is set by use of the second control signal, then delayed, and inputted into a latch circuit. Here, the data signal from outside is also inputted into the latch circuit.

For instance, if the phase setting value is 25%, and if the delay setting value calculating circuit 30 sets 25% of the delay setting value (the first control signal) of the reference clock for the delay element 40, then the delay element 40 delays the strobe signal by 25% of one cycle, that is, by 90 degrees.

FIG. 6 shows an example of a phase relationship among the reference clock, the data signal, the strobe signal before the phase shift by the delay element 40, and the strobe signal after the phase shift by the delay element 40, when the reference clock inputted into the delay element 22 and the strobe signal inputted into the delay element 40 have the frequency of 200 MHz. As shown in FIG. 6, the delay element 40 delays the phase of the strobe signal by 90 degrees delayed by the delay element 40.

### SUMMARY

Here, consider how many stages the delay element 22 of the DLL circuit 20 needs for implementing the phase shift of the strobe signal shown in FIG. 6. In general, the delay element includes buffers and selectors, and a set of a buffer and a selector constitutes one stage.

When a delay of one stage of the delay element 22, or the sum of delays of a buffer and a selector which constitute one stage, is 125 ps, the delay element 22 needs 40 stages, as shown in FIG. 7, for delaying the 200-MHz reference clock by one cycle (5000 ps) under PTV (Process, Voltage, and Temperature) conditions which make the delay the smallest.

This is an example of a case where the frequency of the reference clock is 200 MHz. In general, the DRAM is likely to output strobe signals of multiple frequencies. Accordingly, the delay element 22 needs to include a larger number of stages so as to deal with strobe signals with higher frequencies.

As the number of stages of the delay element in the DLL circuit increases, the circuit size of the DLL circuit or of the delay apparatus as a whole becomes larger. For this reason, it is desired to reduce the number of stages of the delay element, and to accordingly reduce the circuit size of the delay apparatus.

A delay apparatus of an exemplary aspect of the invention, includes a DLL circuit including a delay element, the DLL circuit generating a first control signal for controlling the delay element in order that the delay element delays a reference clock inputted into the delay element by one cycle, and a strobe delay element having a configuration identical to a configuration of the delay element, the strobe delay element delaying the strobe signal inputted from an outside by an amount of delay corresponding to a second control signal. The delay apparatus includes a strobe delay controlling circuit obtaining the second control signal, from the first control signal and an expectation value for the amount of delay to be made by the strobe delay element, and a clock supplying circuit supplying the DLL circuit with the reference clock having a frequency higher than a frequency of the strobe signal.

Note that any apparatus, system and the like into which the method according to the above-described aspect is embodied are effective as aspects of the present invention.

The technique according to the exemplary aspect of the present invention makes it possible to reduce the circuit size of the delay apparatus.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a diagram showing an LSI according to an exemplary embodiment of the present invention;

FIG. 2 is a diagram showing an example of a phase relationship among the signals in the LSI shown in FIG. 1;

FIG. 3 is a diagram showing an example of a delay element of a DLL circuit in the LSI shown in FIG. 1;

FIG. 4 is a diagram showing an example of a strobe delay element in the LSI shown in FIG. 1;

FIG. 5 is a diagram showing a delay apparatus of a related art;

FIG. 6 is a diagram showing an example of a phase relationship among the signals in the delay apparatus shown in FIG. 5; and

FIG. 7 is a diagram showing an example of a delay element of the DLL circuit in the delay apparatus shown in FIG. 5.

### DETAILED DESCRIPTION OF THE EXEMPLARY EMBODIMENTS

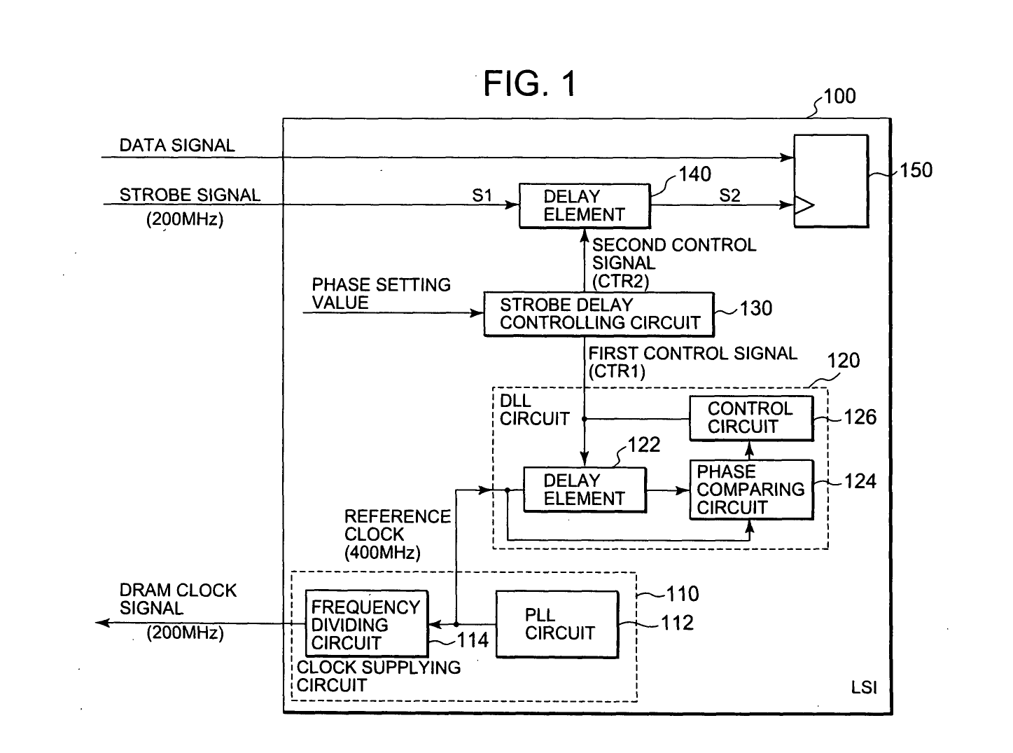

FIG. 1 shows a one-chip LSI 100 according to an exemplary embodiment of the present invention. The LSI 100 is an interface for a DRAM, and includes a clock supplying circuit 110, a DLL circuit 120, a strobe delay controlling circuit 130, a delay element 140, and a latch circuit 150. The functional blocks, except for the latch circuit 150, constitute a delay apparatus or a delay device.

The clock supplying circuit 110 supplies the DLL circuit 120 with a reference clock, and supplies the DRAM with a clock signal (hereinafter referred to as a “DRAM clock signal”). As shown in FIG. 1, the clock supplying circuit 110 includes a PLL circuit 112 and a frequency dividing circuit 114.

The PLL circuit 112 outputs the generated clock signal to the DLL circuit 120, as the reference clock, and to the frequency dividing circuit 114. The frequency dividing circuit 114 divides the frequency of the clock signal generated by the PLL circuit 112, and outputs the clock signal, as the DRAM clock signal to the DRAM. Here, as an example, the frequency of the reference clock is 400 MHz, and the frequency of the DRAM clock signal is 200 MHz which is a half of the frequency of the reference clock.

On the basis of the DRAM clock from the clock supplying circuit 110, the DRAM generates a strobe signal having the same frequency (200 MHz, here) with that of the DRAM clock signal, and outputs the strobe signal together with a data signal to the LSI 100. The data signal is inputted into the latch circuit 150 of the LSI 100. The strobe signal is inputted into the delay element 140 of the LSI 100. After being delayed by the delay element 140, the strobe signal is inputted into the latch circuit 150. Hereinafter, the strobe signal before being delayed by the delay element 140 will be referred to as a strobe signal S1, and the strobe signal having been delayed by the delay element 140 will be referred to as a strobe signal S2.

The DLL circuit 120 has the same configuration as a general DLL circuit has, and includes a delay element 122, a phase comparing circuit 124 and a control circuit 126. The delay element 122 has the same configuration (including the layout) as the delay element 40 for delaying the strobe signal has.

The delay element 122 delays the reference clock corresponding to a first control signal CTR1 from the control circuit 126, and outputs the delayed reference clock to the phase comparing circuit 124. The phase comparing circuit 124 compares the phase of the reference clock before being inputted into the delay element 122 with the phase of the reference clock having been delayed by the delay element 122, and thus outputs a differential signal to the control circuit 126. According to the differential signal from the phase comparing circuit 124, the control circuit 126 generates the first control signal CTR1 to cause the delay element 122 to delay the reference clock by one cycle, and thus executes feedback control of the delay element 122. The first control signal may represent, for instance, a value indicating the number of stages which are used by the delay element 122, for example.

With this configuration, the DLL circuit 120 finally turns into a stable state with an amount of delay which causes the reference clock to be delayed by one cycle, and the first control signal CTR1 represents a value indicating the number of stages which are used by the delay element 122 for delaying the 400-MHz reference clock by one cycle. The first control signal CTR1 is also outputted to the strobe delay controlling circuit 130.

On the basis of an inputted phase setting value and the inputted first control signal CTRL, the strobe delay controlling circuit 130 causes the delay element 140 to generate a second control signal CTR2 by delaying the strobe signal S1 by an amount of delay indicated by the phase setting value, and thus outputs the second control signal CTR2 to the delay element 140. The phase setting value is an expectation value for the amount of delay by which the strobe signal S1 is delayed, and is 25% (90 degrees), for example.

Equation (1) represents how the strobe delay controlling circuit 130 generates the second control signal CTR2 when the phase setting value is denominated in percentage.

Second Control Signal CTR2=Set Phase Value×First Control Signal CTR1×f2/f1 (1)

where f1 denotes the frequency of the reference clock, and f2 denotes the frequency of the strobe signal S1.

For instance, the value of the second control signal CTR2 is half the value of the first control signal CTR1, when, as in the above-described example, the frequency of the reference clock is 400 MHz, the frequency of the first control signal CTR1 is 200 MHz, and the phase setting value is 25%.

The delay element 140 delays the strobe signal S1 by use of the number of stages corresponding to the second control signal CTR2, thus obtaining a strobe signal S2, and then outputs the strobe signal S2 to the latch circuit 150.

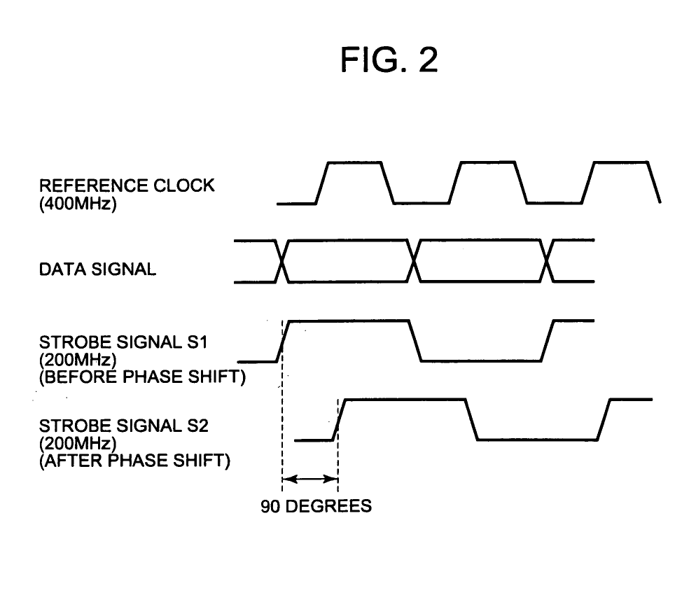

FIG. 2 shows an example of a phase relationship among the reference clock, the data signal, the strobe signal S1 and the strobe signal S2 where the frequency of the reference clock inputted into the delay element 122 is 400 MHz, the frequency of the strobe signal S1 inputted into the delay element 140 is 200 MHz, and the phase setting value is 25%. As shown in FIG. 2, the delay element 140 delays the phase of the strobe signal S1 by 90 degrees (25%) delayed by the delay element 140.

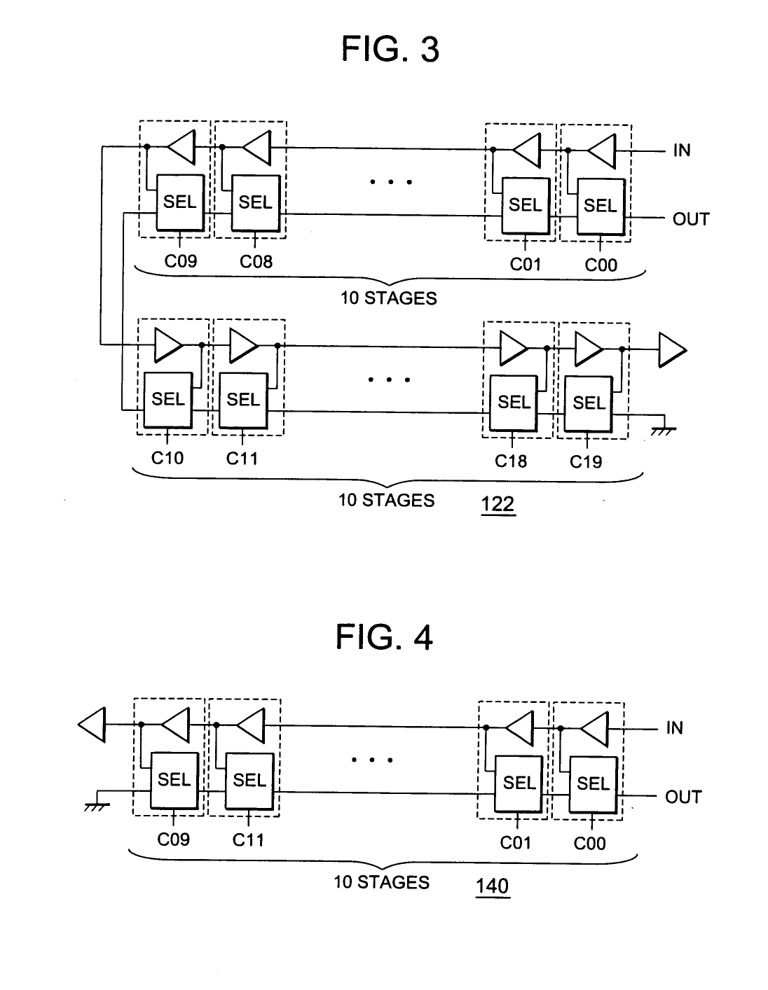

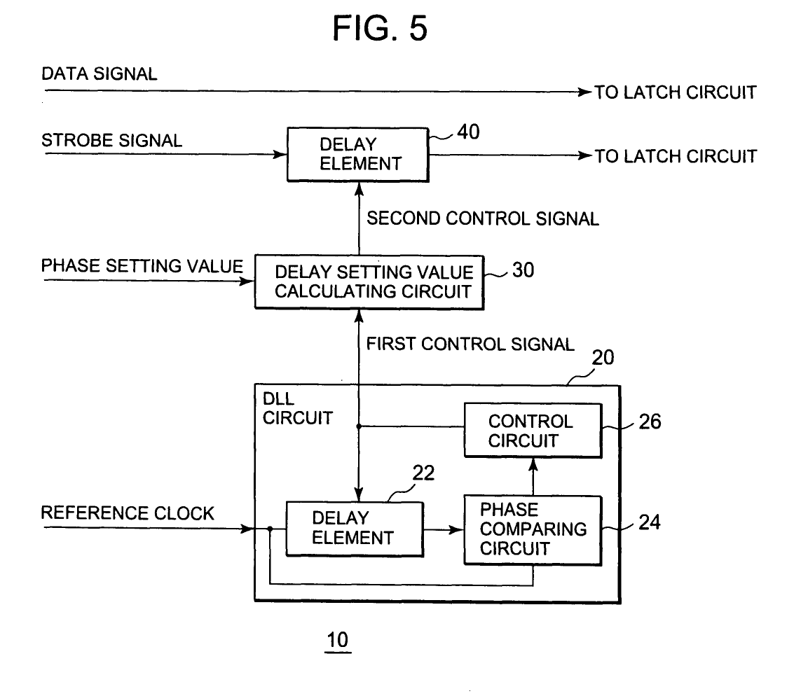

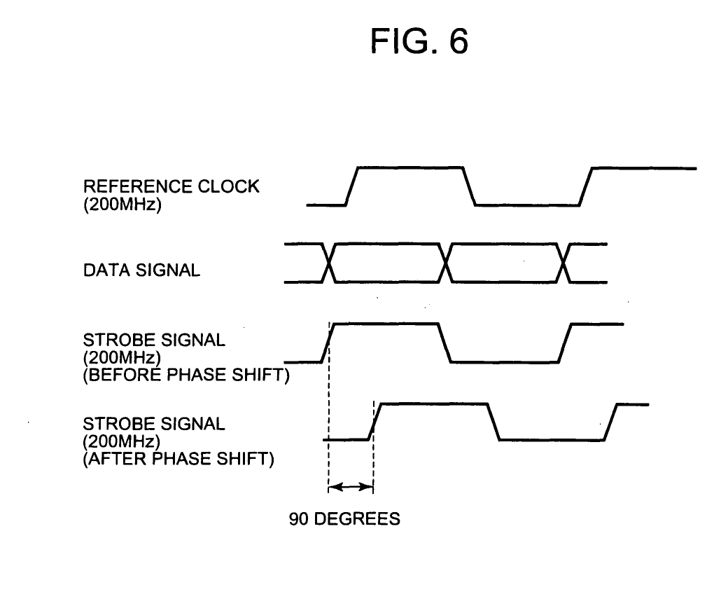

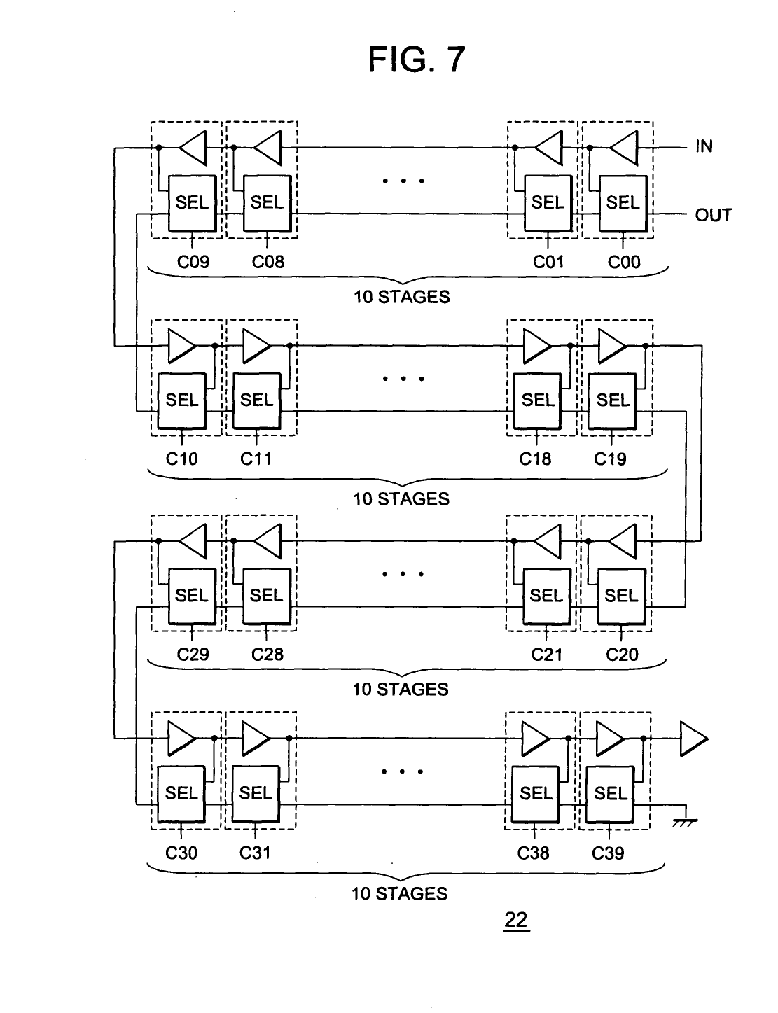

Here, consider how many stages the delay element 122 of the DLL circuit 120 needs for implementing the phase shift of the strobe signal shown in FIG. 2. When a delay of one stage of the delay element 122, or the sum of delays of a buffer and a selector which constitute one stage, is 125 ps, the delay element 22 needs only 20 stages for delaying the 400-MHz reference clock by one cycle (2500 ps) under PTV conditions which make the delay the smallest, as shown in FIG. 3.

Furthermore, in this case, the delay element 140 needs only 10 stages because the delay element 140 delays only by a delay (1250 ps) of a quarter cycle of a delay of the 200-MHz strobe signal S1.

In sum, in the delay device of the related art, the frequency of the reference clock inputted into the delay element of the DLL circuit is equal to the frequency of the strobe signal. In contrast, in the delay apparatus for the LSI 100 according to the exemplary embodiment, the reference clock of a frequency higher than the frequency of the strobe signal S1 inputted into the strobe delay element 140 is inputted into the delay element 122 of the DLL circuit 120. This makes it possible to reduce the number of stages of the delay element 122 of the DLL circuit 120, and thus to reduce the circuit size of the delay apparatus or of the LSI as a whole.

The foregoing descriptions have been provided for the present invention on the basis of the exemplary embodiments. The exemplary embodiments only exemplify the present invention and may be variously altered, increased, reduced and combined, without departing from the scope and spirit of the present invention. Those skilled in the art shall understand that any modification resulting from the alteration, increase, reduction and combination falls within the scope of the present invention.

Further, it is noted that Applicant's intent is to encompass equivalents of all claim elements, even if amended later during prosecution.

What is claimed is:

1. A delay apparatus, comprising:
a delay locked loop (DLL) circuit including a delay element; the DLL circuit generating a first control signal for controlling the delay element in order that the delay element delays a reference clock inputted into the delay element by one cycle;
a strobe delay element having a configuration identical to a configuration of the delay element, the strobe delay element delaying a strobe signal inputted from an outside by an amount of delay corresponding to a second control signal;
a strobe delay controlling circuit which obtains the second control signal, from the first control signal and an expectation value for the amount of delay to be made by the strobe delay element; and
a clock supplying circuit which supplies the DLL circuit with the reference clock having a frequency higher than a frequency of the strobe signal.

2. The delay apparatus according to claim 1, wherein the delay apparatus is a one-chip circuit.

3. The delay apparatus according to claim 1, wherein:
the delay apparatus is included in an interface LSI for a DRAM (Dynamic Random Access Memory);
the clock supplying circuit further divides the frequency of the reference clock to obtain a DRAM clock signal having a frequency equal to the frequency of the strobe signal, and outputs the DRAM clock signal to the DRAM; and
the strobe signal includes a signal for latching data outputted from the DRAM on the basis of the DRAM clock signal.

4. A delay controlling method for a delay apparatus that delays a strobe signal received from an outside,
the delay apparatus including:
a delay locked loop (DLL) circuit including a delay element, the DLL circuit generating a first control signal for controlling the delay element in order that the delay element delays a reference clock inputted into the delay element by one cycle;
a strobe delay element having a configuration identical to a configuration of the delay element, the strobe delay element delaying the strobe signal by an amount of delay corresponding to a second control signal; and
a strobe delay controlling circuit obtaining the second control signal, from the first control signal and an expectation value for the amount of delay to be made by the strobe delay element,
the method comprising:
supplying the DLL circuit with the reference clock having a frequency higher than a frequency of the strobe signal.

5. An integrated circuit, comprising:
a delay locked loop (DLL) circuit which produces a first control signal based on a reference clock;
a strobe delay element which outputs a delayed strobe signal by delaying a strobe signal based on a second control signal;
a strobe delay controlling circuit which produces the second control signal based on the first control signal and a phase setting value; and
a clock generation circuit which produces the reference clock having a frequency higher than a frequency of the strobe signal.

6. The integrated circuit as claimed in claim 5, further comprising:
a latch circuit which latches a data signal based on the delayed strobe signal.

7. The integrated circuit as claimed in claim 5, further comprising:
a frequency divider which divides the reference clock to produce a clock signal which has a frequency equal to a frequency of the strobe signal.
